(19) United States
(12) Patent Application Publication
(10) Pub. No.: US 2024/0105474 A1
(43) Pub. Date: Mar. 28, 2024

(54) LIGHT IRRADIATION TYPE HEAT TREATMENT APPARATUS

(71) Applicant: SCREEN Holdings Co., Ltd., Kyoto (JP)

(72) Inventors: Takahiro KITAZAWA, Kyoto-shi (JP); Yoshio ITO, Kyoto-shi (JP)

(21) Appl. No.: 18/454,103

(22) Filed: Aug. 23, 2023

(30) Foreign Application Priority Data
Sep. 26, 2022 (JP) 2022-152087

(51) Int. Cl. H01L 21/67; F27B 17/00; H05B 1/02; H05B 3/00

(52) U.S. Cl. CPC H01L 21/67115; F27B 17/0025; H05B 1/0233; H05B 3/0047

(57) ABSTRACT

In an auxiliary heating part for performing a preheating treatment on a semiconductor wafer, VCSELs are arranged so as to surround LED lamps arranged in a circular region. The LED lamps irradiate the entire surface of the semiconductor wafer with light, and the VCSELs which emit light of relatively high directivity irradiate a peripheral portion of the semiconductor wafer where a temperature decrease is prone to occur with the light. A common power supply circuit is provided for the LED lamps and VCSELs that irradiate the peripheral portion of the semiconductor wafer with light. Increases in size and costs of power supply circuitry are suppressed because the single power supply circuit supplies power to the two different types of light sources to collectively control the two different types of light sources.

### BACKGROUND OF THE INVENTION

### Field of the Invention

The present invention relates to a heat treatment apparatus which irradiates a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

A typical example of an apparatus for performing such flash lamp annealing includes a heat treatment apparatus in which flash lamps are provided over a chamber that receives a semiconductor wafer therein and halogen lamps are provided under the chamber (as disclosed, for example, in U.S. Patent Application Publication No. 2011/0262115). In the apparatus disclosed in U.S. Patent Application Publication No. 2011/0262115, a semiconductor wafer is preheated by light irradiation from the halogen lamps, and thereafter a front surface of the semiconductor wafer is irradiated with flashes of light from the flash lamps. The preheating is performed by the halogen lamps because only the flash irradiation makes it difficult for the front surface of the semiconductor wafer to reach a target temperature.

Unfortunately, when the preheating is performed by the halogen lamps, a certain amount of time is required until a target output is reached after the halogen lamps turn on, whereas heat radiation continues for a while after the halogen lamps turn off. This has given rise to a problem such that the diffusion length of impurities implanted in the semiconductor wafer becomes relatively long.

The halogen lamps mainly emit infrared light with a relatively long wavelength. Semiconductor wafers of silicon have a low spectral absorptance of infrared light with a longer wavelength of not less than 1 μm in a low temperature range of 500° C. or below. In other words, semiconductor wafers at 500° C. or below do not absorb much infrared light emitted from the halogen lamps. This results in inefficient heating of the semiconductor wafers in the initial stage of the preheating.

To solve such a problem, the use of a plurality of LED lamps for the preheating of a semiconductor wafer has been considered in recent years. The LED lamps have a faster rise and a faster fall in output than the halogen lamps. In addition, the LED lamps mainly emit visible light. Thus, even a semiconductor wafer at a relatively low temperature of 500° C. or below has a high absorptance of light emitted from the LED lamps. Thus, the use of the LED lamps achieves efficient heating treatment even in the initial stage of the preheating.

Even if a semiconductor wafer is preheated using either the halogen lamps or the LED lamps as a light source, heat escapes from a peripheral portion of the semiconductor wafer, which in turn results in a non-uniform temperature distribution such that the temperature of the peripheral portion of the semiconductor wafer is relatively lower than that of a central portion thereof. In recent years, semiconductor manufacturing processes have become increasingly complicated, and the manufacturing costs per semiconductor wafer have continued to accordingly increase. Thus, there is a strong need to increase the percentage of non-defective chips made from a single semiconductor wafer (i.e., to improve yield), and it is hence important to maintain uniformity in in-plane temperature distribution. For a uniform in-plane temperature distribution, it is also contemplated to provide an additional light source for irradiating the peripheral portion of the semiconductor wafer with light exclusively during the preheating. However, the provision of such an additional light source requires multiple power supply circuits to result in increases in size and costs of the power supply circuits.

### SUMMARY

The present invention is intended for a heat treatment apparatus for irradiating a substrate with light to heat the substrate.

According to one aspect of the present invention, the heat treatment apparatus comprises: a chamber for receiving a substrate therein; a holder for holding the substrate in the chamber; a first light source for irradiating the substrate held by the holder with light; and a second light source for irradiating the substrate held by the holder with light, the second light source being different from the first light source, wherein at least part of an irradiation region in which the substrate is irradiated with light from the first light source overlaps an irradiation region in which the substrate is irradiated with light from the second light source. The heat treatment apparatus further comprises a common power supply circuit for supplying power to the first light source and the second light source.

The single power supply circuit supplies power to the first and second light sources which are different in type to collectively control the first and second light sources. This suppresses increases in size and costs of the power supply circuit.

It is therefore an object of the present invention to suppress increases in size and costs of power supply circuitry.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of LED lamps and VCSELs;

FIG. 8 is a schematic view showing the irradiation of a semiconductor wafer with light from the LED lamps and the VCSELs;

FIG. 9 is a diagram showing a power supply circuit for supplying electric power to the LED lamps and the VCSELs;

FIG. 10 is a diagram showing a power supply circuit according to a second preferred embodiment; and

FIG. 11 is a view showing an arrangement of the LED lamps and the VCSELs according to a third preferred embodiment.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

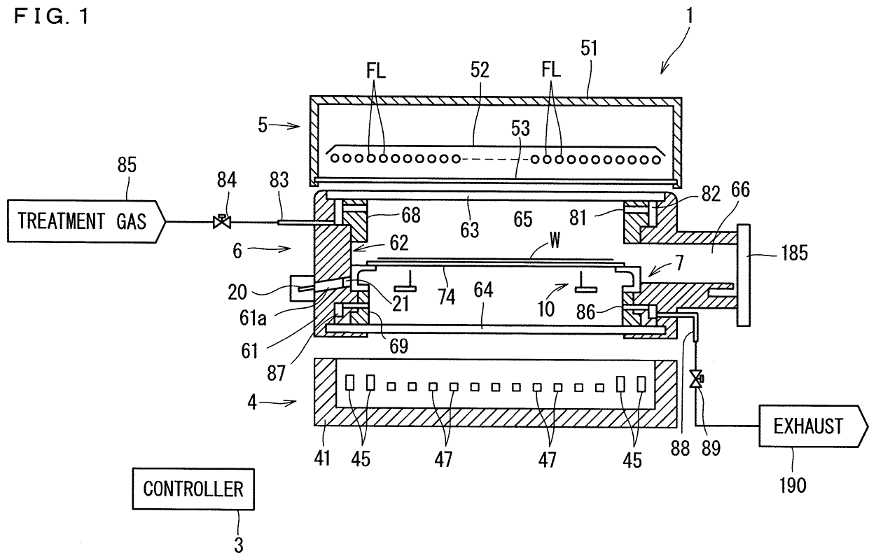

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and an auxiliary heating part 4 including a plurality of LED (Light Emitting Diode) lamps 47 and a plurality of VCSELs (Vertical Cavity Surface Emitting Lasers) 45. The flash heating part 5 is provided over the chamber 6, and the auxiliary heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the auxiliary heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the auxiliary heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. Thus, the radiation thermometer 20 is provided obliquely below the susceptor 74. A transparent window 21 made of barium fluoride material transparent to infrared light in a wavelength range measurable by the radiation thermometer 20 is mounted to an end portion of the through hole 61a which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N 2), reactive gases such as hydrogen (H 2) and ammonia (NH 3), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

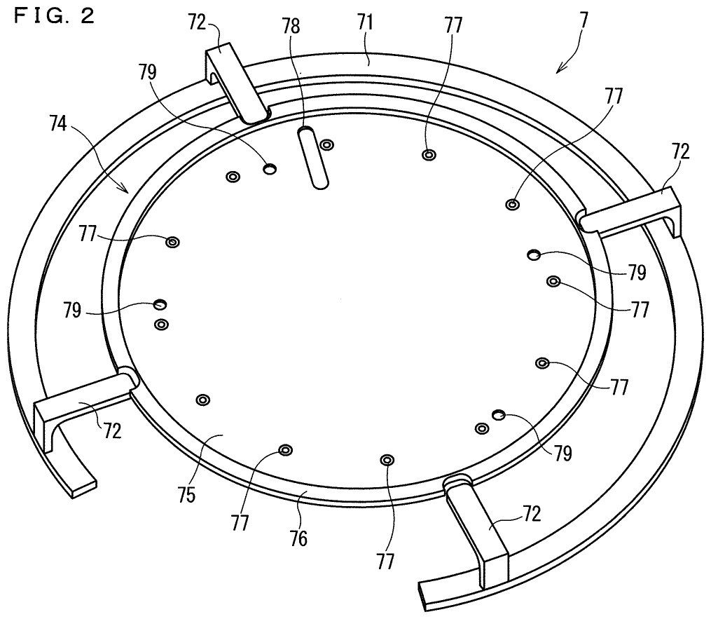

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

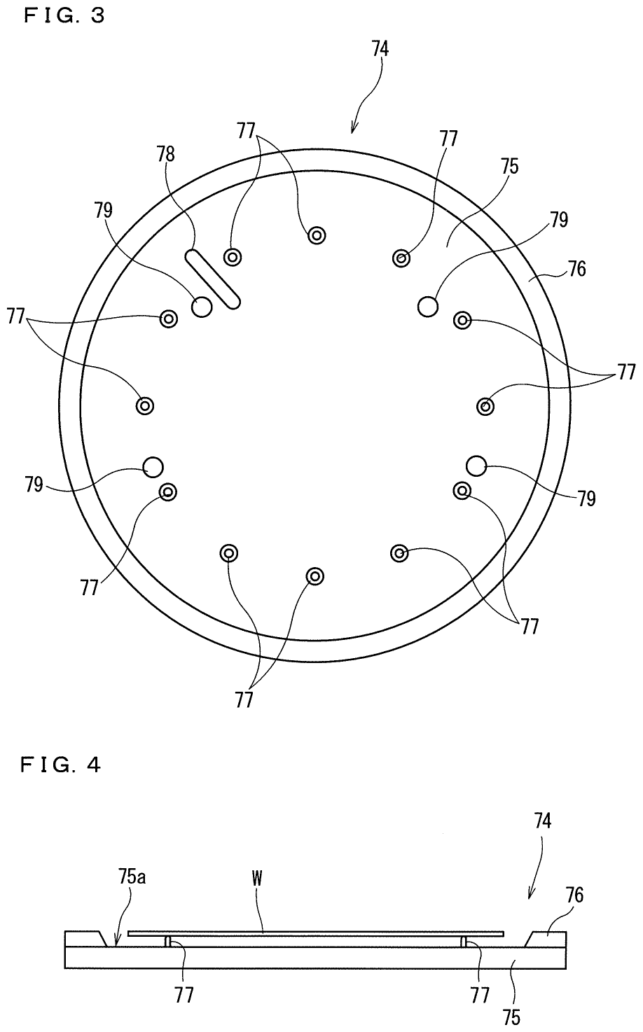

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the radiation thermometer 20 to receive radiation (infrared light) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

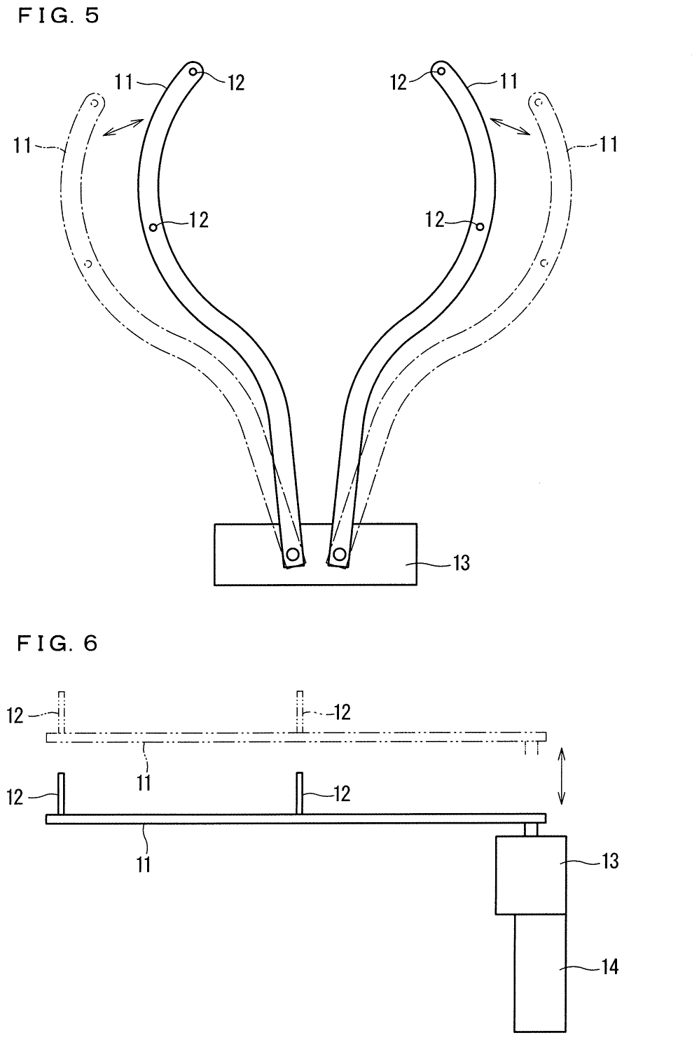

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The auxiliary heating part 4 provided under the chamber 6 includes an enclosure 41 incorporating the LED lamps (a first light source) 47 and the VCSELs (a second light source) 45. In other words, the auxiliary heating part 4 of the present preferred embodiment includes two different types of light sources. The auxiliary heating part 4 is an auxiliary light source that directs light from under the chamber 6 through the lower chamber window 64 toward the heat treatment space 65 to heat the semiconductor wafer W by means of the LED lamps 47 and the VCSELs 45.

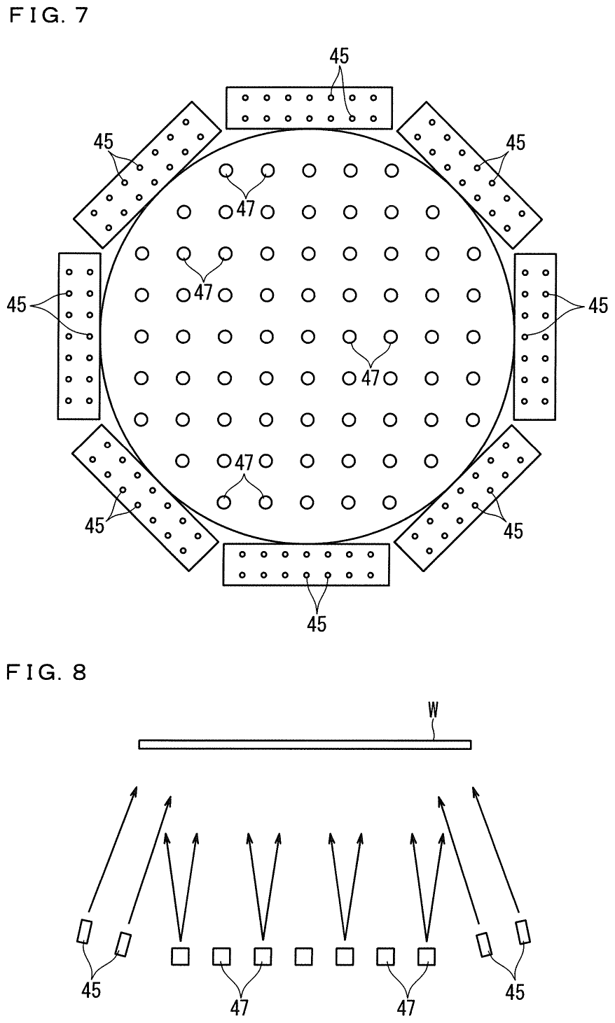

FIG. 7 is a plan view showing an arrangement of the LED lamps 47 and the VCSELs 45. Although the multiplicity of LED lamps 47 and the multiplicity of VCSELs 45 are arranged in the auxiliary heating part 4, the number of LED lamps 47 and the number of VCSELs 45 are shown in simplified form in FIG. 7 for convenience of illustration. Each of the LED lamps 47 and the VCSELs 45 is a point light source, whereas conventional halogen lamps are rod-shaped lamps.

The LED lamps 47 are arranged at a uniform density in a circular region. The size of the circular region in which the LED lamps 47 are arranged is approximately the same as that of the semiconductor wafer W. The LED lamps 47 include light emitting diodes. A light emitting diode is a kind of diode, and emits light because of an electroluminescence effect when a forward voltage is applied thereto.

The VCSELs 45 are arranged so as to surround the circular region in which the LED lamps 47 are arranged. In other words, the LED lamps 47 are arranged in a central portion of the auxiliary heating part 4 and the VCSELs 45 are arranged in a peripheral portion thereof in the first preferred embodiment. A VCSEL (Vertical Cavity Surface Emitting Laser) 45 is a kind of semiconductor laser, and emits light in a direction perpendicular to a front surface of a semiconductor substrate on which a device is provided. The VCSELs 45 are capable of emitting light of a relatively high intensity. The VCSELs 45 are also capable of emitting light of higher directivity than the LED lamps 47. In other words, the LED lamps 47 are wider in light irradiation range than the VCSELs 45. The VCSELs 45 of the first preferred embodiment emit light with a wavelength of 940 nm. The LED lamps 47 and the VCSELs 45 are continuous lighting lamps that emit light continuously for not less than one second.

FIG. 8 is a schematic view showing the irradiation of the semiconductor wafer W with light from the LED lamps 47 and the VCSELs 45. The LED lamps 47 are arranged in the circular region in a horizontal direction. In other words, a plane defined by the arrangement of the LED lamps 47 is a horizontal plane. The circular region in which the LED lamps 47 are arranged is of the same size as the semiconductor wafer W, and is provided in opposed relation to the lower surface of the semiconductor wafer W held by the holder 7. Each of the LED lamps 47 emits light at a relatively wide angle. As a result, the entire lower surface of the semiconductor wafer W is substantially evenly irradiated with light from the LED lamps 47 arranged in the circular region opposed to the lower surface of the semiconductor wafer W.

On the other hand, the VCSELs 45 are arranged outside the semiconductor wafer W held by the holder 7 because the VCSELs 45 are arranged around the circular region in which the LED lamps 47 are arranged. For this reason, the VCSELs 45 are inclined so that the irradiation direction thereof faces the lower surface of the semiconductor wafer W. A peripheral portion of the lower surface of the semiconductor wafer W is irradiated with light from the VCSELs 45 which emit light of relatively high directivity.

If only the LED lamps 47 are used for light irradiation, the semiconductor wafer W shows a tendency to be lower in temperature in a peripheral portion thereof where heat dissipation is liable to occur than in a central portion thereof. In the first preferred embodiment, the irradiation of the peripheral portion of the lower surface of the semiconductor wafer W with light from the VCSELs 45 is performed in addition to the irradiation of the entire lower surface of the semiconductor wafer W with light from the LED lamps 47. The irradiation region of the VCSELs 45 is the peripheral portion of the lower surface of the semiconductor wafer W, whereas the irradiation region of the LED lamps 47 is the entire lower surface of the semiconductor wafer W. In other words, the peripheral portion of the lower surface of the semiconductor wafer W is doubly irradiated with light from the LED lamps 47 and light from the VCSELs 45. This allows light of relatively high directivity from the VCSELs 45 to impinge upon the peripheral portion of the semiconductor wafer W where a temperature decrease is prone to occur when only the LED lamps 47 are used, thereby strongly heating the peripheral portion. Thus, the in-plane temperature distribution of the semiconductor wafer W is made uniform.

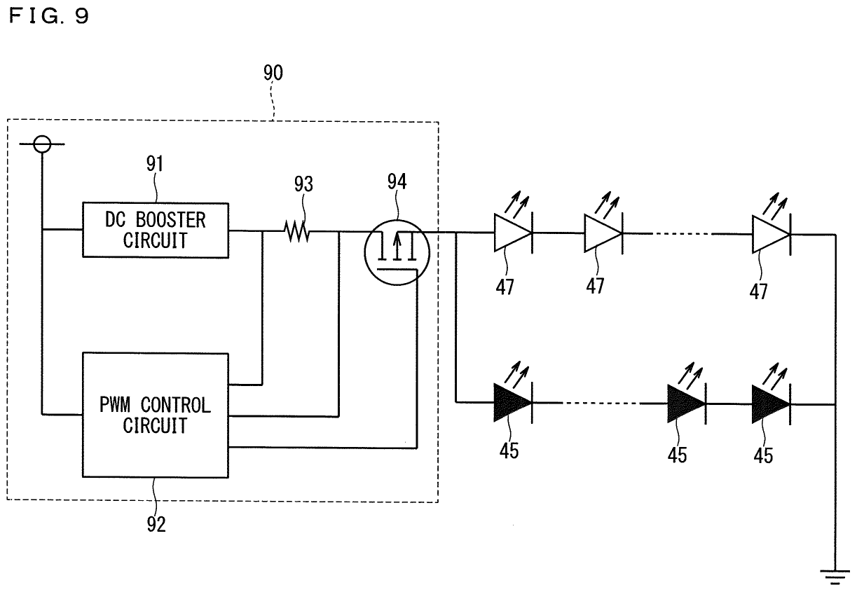

FIG. 9 is a diagram showing a power supply circuit for supplying electric power to the LED lamps 47 and the VCSELs 45. As mentioned above, at least part of the irradiation region in which the semiconductor wafer W is irradiated with light from the LED lamps 47 (the peripheral portion of the wafer in the first preferred embodiment) overlaps the irradiation region in which the semiconductor wafer W is irradiated with light from the VCSELs 45. A common power supply circuit 90 is provided for the LED lamps 47 and VCSELs 45 with the irradiation regions overlapping each other, specifically for the LED lamps 47 and VCSELs 45 that irradiate the peripheral portion of the semiconductor wafer W with light.

The power supply circuit 90 includes a DC booster circuit 91, a PWM control circuit 92, a shunt resistor 93, a MOSFET 94, and the like. The DC booster circuit 91 is a circuit for converting the voltage of current (DC) from a current source. The DC booster circuit 91 outputs a DC at a voltage level higher than an input voltage. The DC booster circuit 91 of the first preferred embodiment outputs a DC current of 50 to 60 V, for example.

The PWM (Pulse Width Modulation) control circuit 92 changes the duty ratio of a pulse wave (the ratio between the pulse width of ON pulses and the pulse width of OFF pulses) to thereby control the ON/OFF of the MOSFET 94. Specifically, the PWM control circuit 92 outputs a pulse signal that repeatedly turns ON and OFF to the gate of the MOSFET 94. While an ON pulse is outputted from the PWM control circuit 92, the MOSFET 94 is in an ON state. While an OFF pulse is outputted from the PWM control circuit 92, the MOSFET 94 is in an OFF state. Thus, the MOSFET 94 repeatedly turns ON and OFF by outputting the pulse signal from the PWM control circuit 92 to the gate of the MOSFET 94.

The shunt resistor 93 is a resistor for measuring the current value of the DC outputted from the DC booster circuit 91. The PWM control circuit 92 changes the duty ratio of the pulse wave, based on the current value measured by the shunt resistor 93.

The MOSFET (Metal Oxide Semiconductor Field Effect Transistor) 94 is a field effect transistor with a MOS structure. In the present preferred embodiment, the MOSFET 94 functions as a switching element for supplying power to the LED lamps 47 and the VCSELs 45. As mentioned above, the opening/closing operation of the MOSFET 94 is controlled by the pulse signal outputted from the PWM control circuit 92.

As shown in FIG. 9. the plurality of LED lamps 47 and the plurality of VCSELs 45 are connected in parallel to the power supply circuit 90. The LED lamps 47 and VCSELs 45 with the irradiation regions overlapping each other, i.e. the LED lamps 47 and VCSELs 45 that irradiate the peripheral portion of the semiconductor wafer W with light, are connected to the power supply circuit 90. This allows power to be supplied from the common power supply circuit 90 to the LED lamps 47 and VCSELs 45 with the irradiation regions overlapping each other.

The LED lamps 47 are connected in series, and the VCSELs 45 are connected in series. The DC booster circuit 91 in the first preferred embodiment outputs a DC of 50 to 60 V, and a voltage drop across each of the LED lamps 47 and VCSELs 45 is approximately several volts. It is hence preferable that seven to eight LED lamps 47 and VCSELs 45 are connected in series to the power supply circuit 90 of the first preferred embodiment.

The PWM control circuit 92 controls the ON/OFF of the MOSFET 94, whereby the power supply circuit 90 controls the outputs from the LED lamps 47 and VCSELs 45 connected to the power supply circuit 90. As the PWM control circuit 92 increases the duty ratio of the pulse wave, the length of time that the MOSFET 94 is open increases, so that the outputs from the LED lamps 47 and VCSELs 45 increase. On the other hand, as the PWM control circuit 92 decreases the duty ratio of the pulse wave, the length of time that the MOSFET 94 is open decreases, so that the outputs from the LED lamps 47 and VCSELs 45 decrease.

The outputs from the LED lamps 47 and VCSELs 45 vary proportionally because the LED lamps 47 and VCSELs 45 with the irradiation regions overlapping each other are connected in parallel to the power supply circuit 90. For example, when the output from the LED lamps 47 increases by 20%, the output from the VCSELs 45 also increases by 20%. That is, the power supply circuit 90 varies the outputs from the LED lamps 47 and VCSELs 45 with the irradiation regions overlapping each other in the same manner.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed. The controller 3 also controls the power supply circuit 90 to adjust the outputs from the LED lamps 47 and VCSELs 45.

The heat treatment apparatus 1 further includes, in addition to the aforementioned components, various cooling structures to prevent an excessive temperature rise in the auxiliary heating part 4, the flash heating part 5, and the chamber 6 because of the heat energy generated from the LED lamps 47, the VCSELs 45, and the flash lamps FL during the heat treatment of a semiconductor wafer W. As an example, a water cooling tube (not shown) is provided in the walls of the chamber 6. Also, the auxiliary heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a treatment operation in the heat treatment apparatus 1 will be described. A typical heat treatment operation for an ordinary semiconductor wafer (product wafer) W that becomes a product will be described. The semiconductor wafer W to be treated is a semiconductor substrate of silicon (Si) implanted with impurities by ion implantation in a preceding step. The activation of the impurities is performed by an annealing process in the heat treatment apparatus 1. A procedure for the treatment of the semiconductor wafer W which will be described below proceeds under the control of the controller 3 over the operating mechanisms of the heat treatment apparatus 1.

Prior to the treatment of the semiconductor wafer W, the valve 84 for supply of gas is opened, and the valve 89 for exhaust of gas is opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is patterned and implanted with impurities is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, light is emitted from the LED lamps 47 and the VCSELs 45 of the auxiliary heating part 4 to start preheating (or assist-heating). The light emitted from the auxiliary heating part 4 is transmitted through the lower chamber window 64 and the susceptor 74 both made of quartz, and impinges upon the lower surface of the semiconductor wafer W. By receiving light irradiation from the auxiliary heating part 4, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the auxiliary heating part 4.

The temperature of the semiconductor wafer W which is on the increase by the irradiation with light from the auxiliary heating part 4 is measured by the radiation thermometer 20. The measured temperature of the semiconductor wafer W is transmitted to the controller 3. The controller 3 controls the power supply circuit 90 to adjust the outputs from the LED lamps 47 and the VCSELs 45 while monitoring whether the temperature of the semiconductor wafer W which is on the increase by the irradiation with light from the auxiliary heating part 4 reaches a predetermined preheating temperature T1 or not. In other words, the controller 3 effects feedback control of the outputs from the LED lamps 47 and the VCSELs 45 so that the temperature of the semiconductor wafer W is equal to the preheating temperature T1, based on the value measured by the radiation thermometer 20. The preheating temperature T1 shall be on the order of 200° to 800° C., preferably on the order of 350° to 600° C., (in the present preferred embodiment, 600° C.) at which there is no apprehension that the impurities implanted in the semiconductor wafer W are diffused by heat.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the outputs from the LED lamps 47 and the VCSELs 45 to maintain the temperature of the semiconductor wafer W at approximately the preheating temperature T1.

The flash lamps FL in the flash heating part 5 irradiate the front surface of the semiconductor wafer W held by the susceptor 74 with a flash of light at the point in time when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2 of 1000° C. or higher. After the impurities implanted in the semiconductor wafer W are activated, the temperature of the front surface of the semiconductor wafer W decreases rapidly. Because of the capability of increasing and decreasing the temperature of the front surface of the semiconductor wafer W in an extremely short time, the heat treatment apparatus 1 achieves the activation of the impurities implanted in the semiconductor wafer W while suppressing the diffusion of the impurities due to heat. It should be noted that the time required for the activation of the impurities is extremely short as compared with the time required for the thermal diffusion of the impurities. Thus, the activation is completed in a short time ranging from about 0.1 to about 100 milliseconds during which no diffusion occurs.

After a predetermined time period has elapsed since the completion of the flash heating treatment, the irradiation with the light from the auxiliary irradiation part 4 also stops. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

In the first preferred embodiment, the VCSELs 45 are arranged so as to surround the LED lamps 47 arranged in the circular region. The LED lamps 47 irradiates the entire surface of the semiconductor wafer W with light, and the VCSELs 45 that emit light of relatively high directivity irradiate the peripheral portion of the semiconductor wafer W with the light. This allows the light of relatively high directivity from the VCSELs 45 to impinge on the peripheral portion of the semiconductor wafer W where a temperature decrease is prone to occur during the preheating, thereby strongly heating the peripheral portion. Thus, the in-plane temperature distribution of the semiconductor wafer W is made uniform during the preheating.

Also, the common power supply circuit 90 is provided for the LED lamps 47 and VCSELs 45 that irradiate the peripheral portion of the semiconductor wafer W with light. The power supply circuit 90 collectively controls the outputs from the LED lamps 47 and VCSELs 45 with the irradiation regions overlapping each other. The provision of the single power supply circuit 90 for supplying power to the two different types of light sources to collectively control the two different types of light sources suppresses increases in size and costs of power supply circuitry, as compared with the provision of individual power supply circuits for the two different types of light sources. In other words, space savings and cost reduction are achieved by reducing the number of power supply circuits.

The outputs from the LED lamps 47 and VCSELs 45 are controlled in the same manner because the common power supply circuit 90 collectively controls the LED lamps 47 and the VCSELs 45. For example, control for decreasing the output from the LED lamps 47 while increasing the output from the VCSELs 45 cannot be exercised. However, there is no problem even if the LED lamps 47 and the VCSELs 45 which are collectively controlled by the common power supply circuit 90 cannot be individually controlled because the LED lamps 47 and the VCSELs 45 have the irradiation regions overlapping each other.

### Second Preferred Embodiment

Next, a second preferred embodiment of the present invention will be described. In the first preferred embodiment, the PWM control circuit 92 and the MOSFET 94 are incorporated in the power supply circuit 90, and the PWM control circuit 92 changes the duty ratio of the pulse wave to adjust the outputs from the LED lamps 47 and VCSELs 45. In the second preferred embodiment, a constant-current circuit is used as the power supply circuit to pass a constant current through the LED lamps 47 and the VCSELs 45.

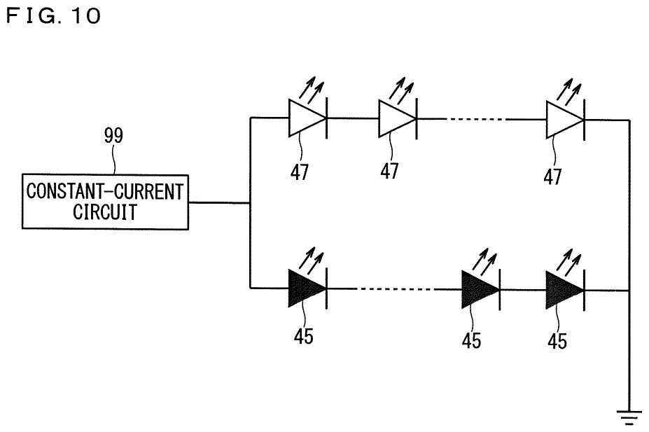

FIG. 10 is a diagram showing the power supply circuit according to the second preferred embodiment. In the second preferred embodiment, a constant-current circuit 99 is provided as the power supply circuit. The constant-current circuit 99 is a power supply circuit that provides a constant current regardless of the load of an element connected thereto and the magnitude of voltage across the element.

The connection of the LED lamps 47 and the VCSELs 45 to the constant-current circuit 99 is in the same manner as in the first preferred embodiment. Specifically, the LED lamps 47 and VCSELs 45 with the irradiation regions overlapping each other are connected in parallel to the constant-current circuit 99. The common constant-current circuit 99 is provided for the LED lamps 47 and VCSELs 45 with the irradiation regions overlapping each other, and power is supplied from the common constant-current circuit 99 to both the LED lamps 47 and the VCSELs 45. The LED lamps 47 are connected in series, and the VCSELs 45 are connected in series.

The second preferred embodiment also suppresses increases in size and costs of power supply circuitry because the single constant-current circuit 99 supplies power to the two different types of light sources to collectively control the two different types of light sources. In the second preferred embodiment, however, the outputs from the LED lamps 47 and VCSELs 45 are fixed because the constant-current circuit 99 passes a constant current to the LED lamps 47 and the VCSELs 45. The configuration and treatment operation of the second preferred embodiment are similar to those of the first preferred embodiment except that the constant-current circuit 99 is used as the power supply circuit.

### Third Preferred Embodiment

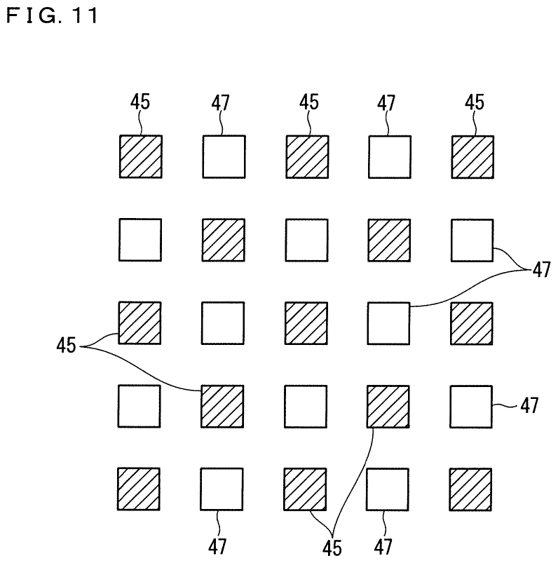

Next, a third preferred embodiment of the present invention will be described. FIG. 11 is a view showing an arrangement of the LED lamps 47 and the VCSELs 45 according to the third preferred embodiment. A plan view of the arrangement of the LED lamps 47 and the VCSELs 45 as seen from above is shown in FIG. 11. In FIG. 11, hollow squares represent the LED lamps 47, and hatched squares represent the VCSELs 45.

In the first preferred embodiment, the VCSELs 45 are arranged so as to surround the LED lamps 47, and the peripheral portion of the semiconductor wafer W is irradiated with the light from the VCSELs 45. In the third preferred embodiment, the LED lamps 47 and the VCSELs 45 are arranged alternately in a lattice pattern, as shown in FIG. 11. The LED lamps 47 and the VCSELs 45 collectively form a checkered pattern.

In the arrangement as shown in FIG. 11, the irradiation region of each of the LED lamps 47 which emits light at a relatively wide angle and the irradiation region of VCSELs 45 adjacent thereto overlap each other. The LED lamps 47 and VCSELs 45 with the irradiation regions overlapping each other are connected to a common power supply circuit. The third preferred embodiment also suppresses increases in size and costs of power supply circuitry because the single power supply circuit supplies power to the two different types of light sources to collectively control the two different types of light sources.

### Fourth Preferred Embodiment

Next, a fourth preferred embodiment of the present invention will be described. Although the LED lamps 47 and the VCSELs 45 are used as the light sources of the auxiliary heating part 4 in the first to third preferred embodiments, halogen lamps are used as the light source of the auxiliary heating part 4 in the fourth preferred embodiment. Each of the halogen lamps is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament.

In the fourth preferred embodiment, two types of halogen lamps with different standards (e.g., lamp tube shapes) are arranged in the auxiliary heating part 4. At least part of the irradiation region of the halogen lamps of one type overlaps the irradiation region of the halogen lamps of the other type. A common power supply circuit is provided for the two types of halogen lamps with the irradiation regions overlapping each other. The power supply for the halogen lamps is an alternating-current (AC) power supply. The power supply circuit adjusts the outputs from the two types of halogen lamps by means of PWM control or phase control.

The fourth preferred embodiment also suppresses increases in size and costs of power supply circuitry because the single power supply circuit supplies power to the two different types of light sources to collectively control the two different types of light sources.

### MODIFICATIONS

While the preferred embodiments according to the present invention have been described hereinabove, various modifications of the present invention in addition to those described above may be made without departing from the scope and spirit of the invention. For example, the VCSELs 45 are arranged so as to surround the LED lamps 47 in the first preferred embodiment, and the LED lamps 47 and the VCSELs 45 are arranged alternately in a lattice pattern in the third preferred embodiment. However, the arrangement of the LED lamps 47 and the VCSELs 45 is not limited to these. The VCSELs 45, which emit light of relatively high directivity, may be arranged so that the light from the VCSELs 45 impinges upon a location (known as a cold spot) of the semiconductor wafer W where a temperature decrease is prone to occur during the heating treatment by means of the LED lamps 47. Even in this case, increases in size and costs of power supply circuitry are suppressed by supplying power from a common power supply circuit to the LED lamps 47 and VCSELs 45 with the irradiation regions overlapping each other.

Although the 30 flash lamps FL are provided in the flash heating part 5 in the aforementioned preferred embodiments, the present invention is not limited to this. Any number of flash lamps FL may be provided. The flash lamps FL are not limited to the xenon flash lamps, but may be krypton flash lamps.

While the invention has been described in detail, the foregoing description is in all aspects illustrative and not restrictive. It is understood that numerous other modifications and variations can be devised without departing from the scope of the invention.

What is claimed is:

1. A heat treatment apparatus for irradiating a substrate with light to heat the substrate, comprising:
a chamber for receiving a substrate therein;
a holder for holding said substrate in said chamber;
a first light source for irradiating said substrate held by said holder with light; and
a second light source for irradiating said substrate held by said holder with light, said second light source being different from said first light source,
wherein at least part of an irradiation region in which said substrate is irradiated with light from said first light source overlaps an irradiation region in which said substrate is irradiated with light from said second light source,
said heat treatment apparatus further comprising
a common power supply circuit for supplying power to said first light source and said second light source.

2. The heat treatment apparatus according to claim 1,
wherein said second light source emits light of higher directivity than said first light source.

3. The heat treatment apparatus according to claim 2,
wherein said first light source is an LED lamp; and
wherein said second light source is a vertical cavity surface emitting laser.

4. The heat treatment apparatus according to claim 3,
wherein said power supply circuit includes a PWM control circuit.

5. The heat treatment apparatus according to claim 3,
wherein said power supply circuit includes a constant-current circuit.

6. The heat treatment apparatus according to claim 2,
wherein the irradiation region of said second light source is a peripheral portion of said substrate.

7. The heat treatment apparatus according to claim 3, further comprising
a flash lamp for irradiating said substrate held by said holder with a flash of light.
